(19) United States
(12) Patent Application Publication
(10) Pub. No.: US 2010/0265648 A1
(43) Pub. Date: Oct. 21, 2010

(54) Information processing device

(75) Inventor: Takayuki Hirabayashi, Tokyo (JP)

Correspondence Address: LERNER, DAVID, LITTENBERG,;KRUMHOLZ & MENTLIK, 600 SOUTH AVENUE WEST, WESTFIELD, NJ, 07090, US

(73) Assignee: Sony Corporation, Tokyo (JP)

(21) Appl. No.: 12/798,633

(22) Filed: Apr. 8, 2010

(30) Foreign Application Priority Data
Apr. 21, 2009 (JP) P2009-103024

(51) Int. Cl. H05K 7/16

(52) U.S. Cl. 361/679.28

(57) ABSTRACT

An information processing device, includes: a display means including a receiving surface for receiving data transmitted by wireless communication; and a supporting means including a transmitting surface for transmitting the data by the wireless communication and supporting the display means, wherein the supporting means supports the display means in a position in which the wireless communication can be performed.

### CROSS-REFERENCE TO RELATED APPLICATION

The present application claims priority from Japanese Patent Application No. JP 2009-103024 filed in the Japanese Patent Office on Apr. 21, 2009, the entire content of which is incorporated herein by reference.

### BACKGROUND OF THE INVENTION

1. Field of the Invention

The present invention relates to an information processing device, and particularly relates to an information processing device capable of connecting a body and a display included in the information processing device by radio.

2. Description of the Related Art

In related art, as an information processing device in which a body and a display are integrally formed, there exists, for example, a so-called notebook personal computer (for example, refer to JP-A-2004-253939 (Patent Document 1)).

In the notebook personal computer, the body and the display is connected by a hinge and the like, and the display is rotated about the hinge as a rotational axis to thereby open and close the display.

### SUMMARY OF THE INVENTION

In the notebook personal computer in related art, the body and the display are connected by cables for supplying a video signal and the like, which is housed in the hinge.

Accordingly, the cables closely housed and routed in the hinge are likely to be broken due to abrasion, for example, by repeatedly opening and closing the display. In such case, the video signal and the like are not supplied from the body to the display, as a result, it is difficult to display a display screen on the display.

Also in the notebook personal computer in related art, it is necessary to arrange cables between the body and the display, therefore, space (vacancy) for arranging cables have to be provided between the body and the display.

Accordingly, the angle and orientation of the display are limited, and degree of freedom in designing the notebook personal computer is likely to be reduced.

In view of the above, it is desirable to connect the body and display by ratio.

According to an embodiment of the invention, there is provided an information processing device including a display means having a receiving surface for receiving data transmitted by wireless communication and a supporting means having a transmitting surface for transmitting the data by the wireless communication and supporting the display means, in which the supporting means supports the display means in a position in which the wireless communication can be performed.

The supporting means can support the display means in a position in which the data transmitted from the transmitting surface can be received only by the receiving surface.

The supporting means can support the display means so as to be detachable.

The display means has a rectangular parallelepiped shape and the supporting means supports the display means in landscape orientation or in portrait orientation.

The display means can include a first receiving surface receiving the data transmitted from the transmitting surface by the wireless communication when the display means is supported in landscape orientation, and a second receiving surface receiving the data transmitted from the transmitting surface by the wireless communication when the display means is supported in portrait orientation.

The first receiving surface and the second receiving surface can be the same receiving surface.

The supporting means can further support the display means so as to be rotatable about the supporting means as a rotational axis.

The supporting means can support the display means in a position in which the wireless communication is not capable of being performed when the wireless communication is not performed.

The supporting means can support the display means so as to slide in a given direction.

The display means can include a first receiving surface receiving the data transmitted from the transmitting surface by the wireless communication when the display means is supported in the state of being slid in the given direction, and a second receiving surface different from the first receiving surface, receiving the data transmitted from the transmitting surface by the wireless communication when the display device is supported in the state of not being slid in the given direction.

The supporting means can include a first transmitting surface transmitting the data by the wireless communication when the display means is supported in the state of being slid in the given direction, and a second transmitting surface different from the first transmitting surface, transmitting the data by the wireless communication when the display device is supported in the state of not being slid in the given direction.

The supporting means can support the display means so that a display screen of the display means is directed to a given direction or a direction opposite to the given direction.

The display means can display an image corresponding to the data received by the receiving surface, and the transmitting surface included in the supporting means can transmit the data at a transfer speed corresponding to a display speed of the image displayed by the display means.

The supporting means can support the display means in a position in which the transmitting surface faces the receiving surface.

The transmitting surface included in the supporting means and the receiving surface included in the display means can perform the wireless communication by TransferJet (Registered Trademark of Sony Corporation).

According to an embodiment of the invention, a display means including a receiving surface receiving data transmitted by wireless communication is supported by a supporting means including a transmitting surface transmitting the data by the wireless communication and supporting the display means in a position in which the wireless communication can be performed.

According to an embodiment of the invention, the body and the display can be connected by radio.

### BRIEF DESCRIPTION OF THE DRAWINGS

FIG. 1 is a view showing an appearance example according to a first embodiment;

FIG. 2 is a view showing an appearance example according to a second embodiment;

FIG. 3 is another view showing an appearance example according to the second embodiment;

FIG. 4 is a view showing an appearance example according to a third embodiment;

FIG. 5 is another view showing an appearance example according to the third embodiment;

FIG. 6 is a view showing an appearance example according to a fourth embodiment;

FIG. 7 is a view showing an appearance example according to a fifth embodiment;

FIG. 8 is a view showing an appearance example according to a sixth embodiment;

FIG. 9 is another view showing an appearance example according to the sixth embodiment;

FIG. 10 is further another view showing an appearance example according to the sixth embodiment;

FIG. 11 is a view showing an appearance example according to a seventh embodiment;

FIG. 12 is another view showing an appearance example according to the seventh embodiment;

FIG. 13 is further another view showing an appearance example according to the seventh embodiment; and

FIG. 14 is a view showing an appearance example according to an eighth embodiment.

### DESCRIPTION OF THE PREFERRED EMBODIMENTS

Hereinafter, best modes for carrying out the invention (refer to as embodiments in the following description) will be explained. The explanation will be made in the following order.

1. First Embodiment (Example in which a body and a display are detachable)

2. Second Embodiment (Example in which couplers are provided horizontally and vertically at a corner portion of the display)

3. Third Embodiment (Example in which couplers are provided obliquely at a corner of the display)

4. Fourth Embodiment (Example in which the display is rotatable)

5. Fifth Embodiment (Example in which the display can be also mounted upside down)

6. Sixth Embodiment (Example of a notebook personal computer)

7. Seventh Embodiment (Example of a cellular phone device which can slide)

8. Eighth Embodiment (Another example of a cellular phone device which can slide)

9. Modification Embodiment

### First Embodiment

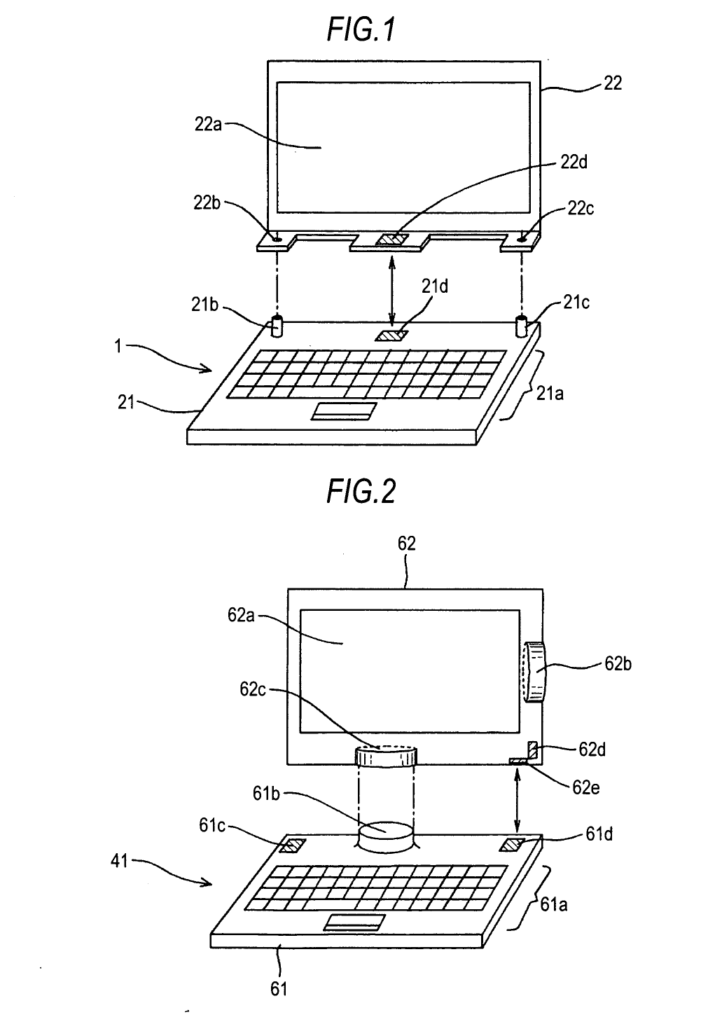

FIG. 1 shows an appearance example of a single unit computer 1 seen from the front according to a first embodiment.

The single unit personal computer (referred to as a single unit PC in the following description) includes a body 21 and a display portion 22 attachable to and detachable from the body 21.

The body 21 supplies a video signal to the display portion 22 by a close-range high speed wireless communication while mounting (supporting) the display portion 22 to display an image corresponding to the video signal.

Here, the close-range high speed wireless communication is wireless communication performed between the body 21 and the display portion 22, which is the wireless communication in which a wireless signal is exchanged between the body 21 and the display portion 22 which are in close proximity to each other to a degree that the signal is not received by communication devices other than the body 21 and the display portion 22.

In the close-range high speed wireless communication, the video signal is transferred at high speed from the body 21 to the display portion 22 at a transfer speed (for example, a transfer speed in which the image displayed on the display portion 22 is not frozen) in accordance with a display speed of the image corresponding to the video signal, which is displayed by the display portion 22.

As the close-range high speed wireless communication, there exists TransferJet (Registered Trademark of Sony Corporation) performing wireless communication at a transfer rate approximately of 560 [Mbps] at a close range of approximately 3 cm by electromagnetic waves, however, other close-range high speed wireless communications and the like different from TransferJet (Trademark) can be used in the first to eighth embodiments, in addition to TransferJet (Trademark).

The body 21 is provided with, in addition to an operation portion 21a such as a keyboard and a touch pad, supporting columns 21b, 21c used for supporting the display portion 22 and a coupler 21d which is an antenna including a transmitting/receiving surface for transmitting or receiving data such as a video signal by electromagnetic waves in the close-range high speed wireless communication.

The body 21 includes a CPU (central processing unit), a ROM (read only memory), a RAM (random access memory) and an HDD (hard disk drive) and the like.

The display portion 22 is provided with, in addition to an LCD (liquid crystal display) 22a, supporting holes 22b, 22c pierced and fixed by supporting columns 21b, 21c respectively and a coupler 22d which is an antenna having a transmitting/receiving surface for transmitting or receiving data by electromagnetic waves in the close-range high speed wireless communication.

When the body 21 supports the display portion 22 by the supporting holes 22b, 22c in the display portion 22 being pierced and fixed by the supporting columns 21b, 21c in the body 21, the transmitting/receiving surface of the coupler 21d and the transmitting/receiving surface of the coupler 22d are arranged face to face (arranged so as to face each other) at close range.

In this case, the close-range high speed wireless communication using the coupler 21d and the coupler 22d is started between the body 21 and the display portion 22 in response to the arrangement of the transmitting/receiving surfaces facing each other.

Additionally, power is supplied from the body 21 to the display portion 22 by an existing feeding method of supplying power by radio while the display portion 22 is mounted on the body 21.

It is also preferable that a battery is built in the display portion 22 and feeding is started by the battery in response to the supply of the video signal from the body 21 using the close-range high speed wireless communication.

As the feeding method performed by the body 21 with respect to the display portion 22 while the body 21 supports the display portion 22, a wired feeding method can be applied in addition to the wireless feeding method.

The feeding method performed by the body 21 with respect to the display portion 22 while the body 21 supports the display portion 22 is the same in the later described second to eighth embodiments, therefore, explanation thereof will be omitted.

In the first embodiment, the video signal from the body 21 to the display portion 22 is supplied by the close-range high speed wireless communication by radio, instead of the wired communication.

Since it is not necessary to connect the body 21 to the display portion 22 by cables in the first embodiment, a situation in which the video signal is not supplied from the body 21 to the display portion 22 by breaking of cables can be prevented.

Additionally, for example, it is not necessary to secure the space for arranging cables between the body 21 and the display portion 22, therefore, it is possible to prevent the degree of freedom in designing the single unit PC 1 from being limited by securing the space for arranging cables.

Furthermore, since the body 21 and the display portion 22 are not connected by cables in the first embodiment, it is possible to exchange the display portion 22 with another display portion easily.

Therefore, for example, even when the display portion 22 is out of order, the display portion 22 can be easily exchanged with another display portion which normally operates. The display portion 22 can be also exchanged with a display portion having a different size in accordance with application easily.

### Second Embodiment

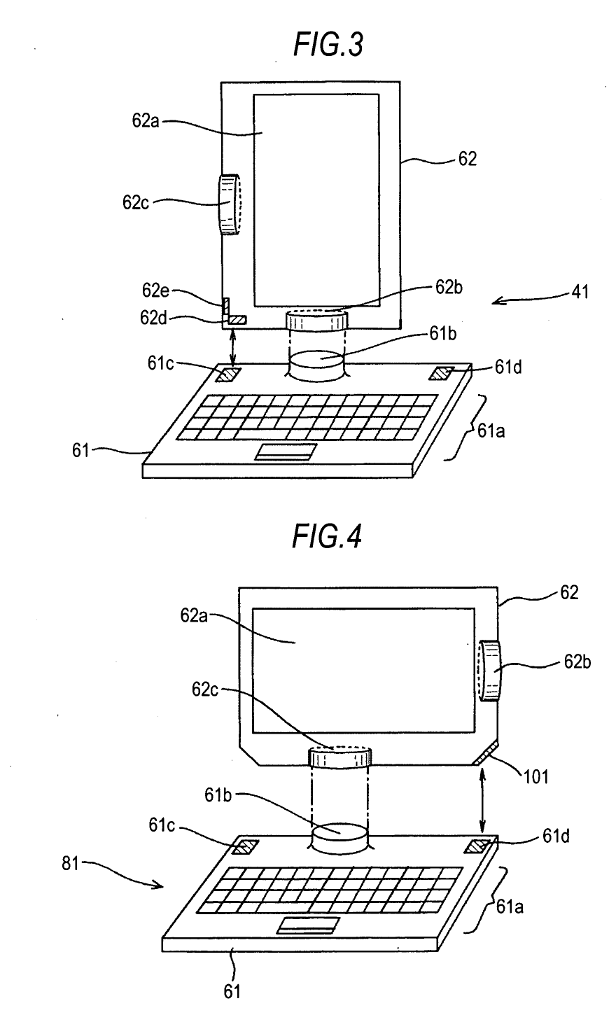

Next, a single unit PC 41 according to a second embodiment will be explained with reference to FIG. 2 and FIG. 3.

FIG. 2 and FIG. 3 show appearance examples of the single unit PC 41 seen from the front according to the second embodiment.

The single unit PC 41 includes a body 61 and a display portion 62 attachable to and detachable from the body 61 in landscape orientation or in portrait orientation.

The body 61 supplies a video signal to the display portion 62 by a close-range high speed wireless communication while supporting the display portion 62 to display an image corresponding to the video signal.

The body 61 is provided with, in addition to an operation portion 21a such as a keyboard and a touch pad, a convex portion 61b used for supporting the display portion 62 and couplers 61c, 61d formed in the same manner as the coupler 21d of FIG. 1.

The display portion 62 has an approximately rectangular parallelepiped shape.

The display portion 62 is provided with, in addition to a LCD 62a, concave portions 62b, 62c to be fitted and fixed to the convex portion 61b and couplers 62d, 62e formed in the same manner as the coupler 22d of FIG. 1 at a lower right position in the drawing.

When the convex portion 61b of the body 61 is fitted to the concave portion 62c of the display portion 62 (in the case where the body 61 supports the display portion 62 in landscape orientation) as shown in FIG. 2, the transmitting/receiving surface of the coupler 61d of the body 61 and the transmitting/receiving surface of the coupler 62e of the display portion 62 are arranged so as to face each other at close range.

On the other hand, when the convex portion 61b of the body 61 is fitted to the concave portion 62b (when the body 61 supports the display portion 62 in portrait orientation) as shown in FIG. 3, the transmitting/receiving surface of the coupler 61c of the body 61 and the transmitting/receiving surface of the coupler 62d of the display portion 62 are arranged so as to face each other at close range.

In both cases shown in FIG. 2 and FIG. 3, the close-range high speed wireless communication is started between the body 61 and the display portion 62 in response to the arrangement of the transmitting/receiving surfaces facing each other.

In the second embodiment, the couplers 61c, 61d are arranged at the body 61 and the couplers 62d, 62e are arranged at the display portion 62 respectively so that the transmitting/receiving surfaces of the coupler 61d and the coupler 62e face each other when the body 61 supports the display portion 62 in landscape orientation (in the state shown in FIG. 2) as well as so that the transmitting/receiving surfaces of the coupler 61c and the coupler 62d face each other when the body 61 supports the display portion 62 in portrait orientation (in the state shown in FIG. 3).

When the transmitting/receiving surfaces of the couplers are arranged face to face, the close-range high speed wireless communication is performed.

Therefore, in the second embodiment, it is not necessary to connect the body 61 and the display portion 62 by wire.

Accordingly, it is possible to change the state of the display portion 62 to be landscape orientation or portrait orientation according to application in the second embodiment.

In the second embodiment, the coupler 62d is provided at the display portion 62 so that the close-range high speed wireless communication can be performed when the display portion 62 is mounted in portrait orientation.

However, when a new coupler is horizontally provided at a lower right position in the display portion 62 instead of the coupler 62d in the display portion 62 in FIG. 3 and the display portion 62 is mounted so as to approach the right edge from the center (with an offset), the close range high speed wireless communication can be performed by using the new coupler and the coupler 61d of the body 61.

Since the coupler 61c of the body 61 is not necessary in this case, a simpler configuration can be realized as compared with the case in which the couplers 61c, 61d are provided at the body 61.

### Third Embodiment

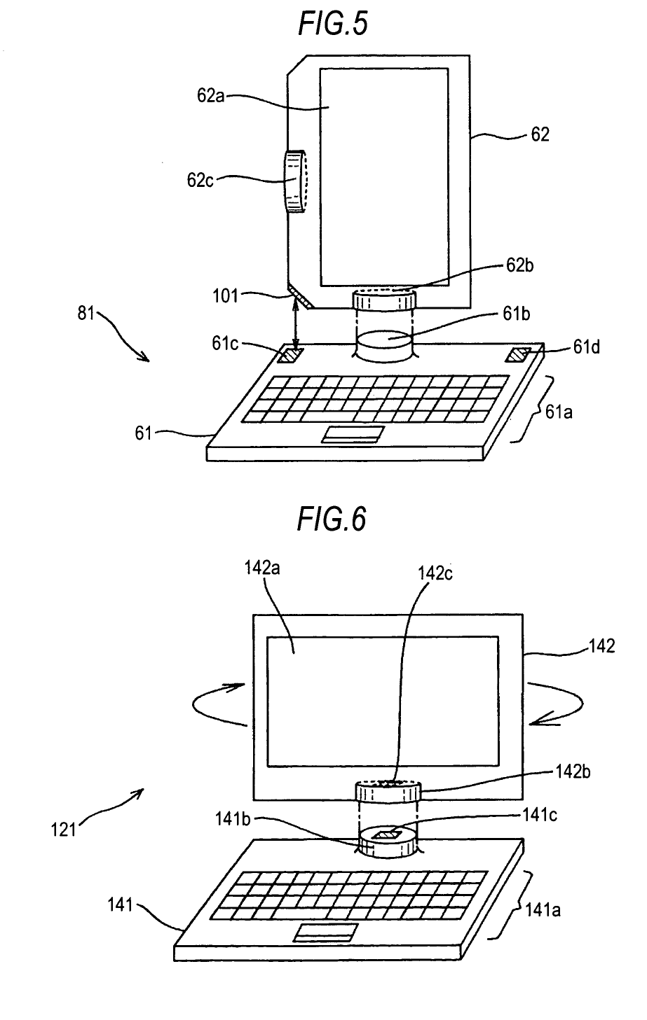

Next, a single unit PC 81 according to a third embodiment which includes one coupler 101 instead of two couplers 62d and 62e will be explained with reference to FIG. 4 and FIG. 5.

FIG. 4 and FIG. 5 show appearance examples of the single unit PC 81 seen from the front according to the third embodiment.

In the single unit PC 81, the same signs are given to components formed in the same manner as the single unit PC 41 according to the second embodiment, therefore, explanation thereof will be omitted below.

That is, the single unit PC 81 is formed in the same manner as the single unit PC 41 except that the coupler 101 is provided instead of the coupler 62d and coupler 62e in the display portion 62.

In the display portion 62, the coupler 101 is provided obliquely at a corner portion of the lower right direction of the display portion 62 in FIG. 4 so that an angle with respect to the horizontal direction of FIG. 4 is 45 degrees.

When the convex portion 61b of the body 61 is fitted to the concave portion 62c of the display portion 62 (when the body 61 supports the display portion 62 in landscape orientation) as shown in FIG. 4, the transmitting/receiving surface of the coupler 61d of the body 61 and the transmitting/receiving surface of the coupler 101 of the display portion 62 are arranged at close range so that the angle formed by respective transmitting/receiving surfaces is 45 degrees.

When the convex portion 61b of the body 61 is fitted to the concave portion 62b of the display portion 62 (when the body 61 supports the display portion 62 in portrait orientation) as shown in FIG. 5, the transmitting/receiving surface of the coupler 61c of the body 61 and the transmitting/receiving surface of the coupler 101 of the display portion 62 are arranged at close range so that the angle formed by respective transmitting/receiving surfaces is 45 degrees.

In both cases shown in FIG. 4 and FIG. 5, the close-range high speed wireless communication is started between the body 61 and the display portion 62 in response to the arrangement of the transmitting/receiving surfaces at close range in the state in which the angle formed by the respective transmitting/receiving surfaces is 45 degrees.

In the third embodiment, when the body 61 supports the display portion 62 in landscape orientation (the state shown in FIG. 4), the transmitting/receiving surfaces of the coupler 61d of the body 61 and the coupler 101 of the display portion 62 are arranged so that the angle formed by the respective transmitting/receiving surfaces is 45 degrees.

In the third embodiment, when the body 61 supports the display portion 62 in portrait orientation (the state shown in FIG. 5), the transmitting/receiving surfaces of the coupler 61c of the body 61 and the coupler 101 of the display portion 62 are arranged so that the angle formed by the transmitting/receiving surfaces is 45 degrees.

Therefore, in the third embodiment, it is possible to reduce the number of couplers to be provided at the display portion 62 as compared with the case according to the second embodiment.

Also in the third embodiment, when the respective transmitting/receiving surfaces of the couplers are arranged so that the angle formed by the transmitting/receiving surfaces is 45 degrees, the close-range high speed wireless communication by radio is performed to control the display portion 62.

Accordingly, it is not necessary to connect the body 61 to the display portion 62 by wire in the third embodiment.

### Fourth Embodiment

Next, FIG. 6 shows an appearance example of a computer 121 according to a fourth embodiment.

The computer 121 includes a body 141 and a display portion 142 which is rotatable with respect to the body 141.

The body 141 supplies a video signal to the display portion 142 by the close-range high speed wireless communication while supporting the display portion 142 to display an image corresponding to the video signal.

The body 141 is provided with, in addition to an operation portion 141a such as a keyboard and a touch pad, a convex portion 141b used for supporting the display portion 142 and a coupler 141c formed in the same manner as the coupler 21d of FIG. 1 at the center of the convex portion 141b.

The display portion 142 is provided with, in addition to a LCD 142a, a concave portion 142b which is fitted and fixed to the convex portion 141b, rotatable about the convex portion 141b as a rotational axis and a coupler 142c formed in the same manner as the coupler 22b of FIG. 1 inside the concave portion 142b.

When the body 141 supports the display portion 142 by the convex portion 141b of the body 141 being fitted to the concave portion 142b of the display portion 142 as shown in FIG. 6, the transmitting/receiving surface of the coupler 141c of the body 141 and the transmitting/receiving surface of the coupler 142c of the display portion 142 are arranged face to face at close range.

In this case, the close-range high speed wireless communication using the coupler 141c and the coupler 142c is started between the body 141 and the display portion 142 in response to the arrangement of the respective transmitting/receiving surfaces facing each other.

In the fourth embodiment, when the body portion 141 supports the display portion 142, the transmitting/receiving surfaces of the coupler 141c of the body 141 and the coupler 142c of the display portion 142 are arranged so as to face each other. Then, the close-range high speed wireless communication by radio is performed in response to the arrangement of the transmitting/receiving surfaces facing each other.

Accordingly, it is not necessary to connect the body 141 to the display portion 142 by wire in the fourth embodiment.

Also in the fourth embodiment, when the convex portion 141b of the body 141 is fitted to the concave portion 142b of the display portion 142, the display portion 142 (concave portion 142b) can be rotated about the convex portion 141b of the body 141 as the rotational axis.

Accordingly, for example, it is possible to allow a person sitting opposite to an operator to view a surface on which the LCD 142a of the display portion 142 is arranged easily just by rotating the display portion 142.

Therefore, it is not necessary to move the entire computer 121 in order to allow the person sitting opposite to the operator to view the LCD 142a of the display portion 142.

It is also possible to rotate the display portion 142 about the convex portion 141b as the rotational axis clockwise or counterclockwise any number of times (more than 360 degrees).

Therefore, after the surface on which the LCD 142a of the display portion 142 is arranged is allowed to be viewed by the person sitting opposite to the operator by rotating the display portion 142, the surface on which the LCD 142a is arranged can be directed toward the user by rotating the display portion 142 both clockwise and counterclockwise.

### Fifth Embodiment

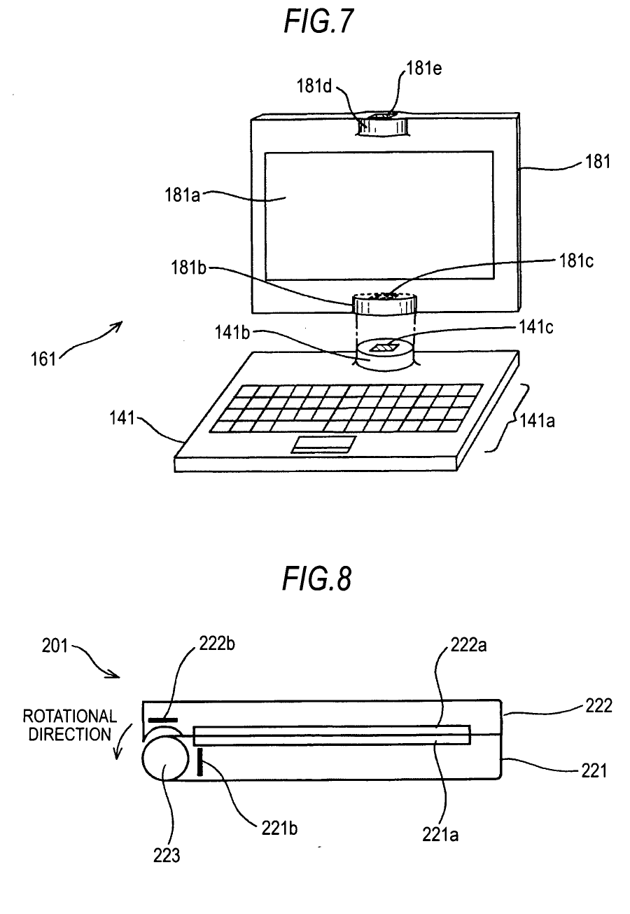

Next, FIG. 7 shows an appearance example of a computer 161 seen from the front according to a fifth embodiment.

In the computer 161, the same signs are given to components formed in the same manner as the computer 121 according to the fourth embodiment, therefore, explanation thereof will be omitted below.

That is, the computer 161 is formed in the same manner as the computer 121 except that a display portion 181 is provided instead of the display portion 142.

The display portion 181 includes, in addition to an LCD 181a, a concave portion 181b to be fitted and fixed to the convex portion 141b so that a surface on which the LCD 181a is provided is directed toward the body 141 side and a coupler 181c formed in the same manner as the coupler 22d of FIG. 1 inside the concave portion 181b.

The display portion 181 also includes a concave portion 181d to be fitted and fixed to the convex portion 141b so that the surface on which the LCD 181a is provided is directed to the opposite side of the body 141 side and a coupler 181e formed in the same manner as the coupler 22d of FIG. 1 inside the concave portion 181d.

The same display screen (not display screens having different orientations) is displayed on the LCD 181a both in the case in which the convex portion 141b is fitted to the concave portion 181d and in the case in which the convex portion 141b is fitted to the concave portion 181b.

In the fifth embodiment, the body 141 can support the display portion 181 so that the surface on which the LCD 181a is provided is directed to the body 141 side as well as the body 141 can support the display portion 181 so that the surface on which the LCD 181a is provided is directed to the opposite side of the body 141 side.

Accordingly, for example, it is possible to allow a person sitting opposite to the operator to view a surface on which the LCD 181a of the display portion 181 is provided just by changing the connection of the display portion 181.

Also in the fifth embodiment, data is exchanged by the close-range high speed wireless communication by radio, therefore, it is not necessary to connect the body 141 to the display 181 by wire.

### Sixth Embodiment

Next, a so-called notebook personal computer 201 according to a sixth embodiment will be explained with reference to FIG. 8 to FIG. 10.

FIG. 8 shows an appearance example of a notebook personal computer 201 seen from a side surface.

The notebook personal computer (referred to as a notebook PC in the following description) 201 includes a body 221, a display portion 222 and a hinge portion 223. In FIG. 8, the notebook PC 201 is in a state in which the body 221 and the display portion 222 meet (in a state in which the body 221 is in contact with the display portion 222).

The body 221 includes, in addition to a keyboard, a touch pad and the like, a coupler 221b formed in the same manner as the coupler 21d of FIG. 1 inside the body 221.

The display portion 222 includes, in addition to an LCD 222a, a coupler 222b formed in the same manner as the coupler 22d of FIG. 1 at a portion connected to the hinge portion 223.

The body 221 and the display portion 222 are connected to the hinge portion 223, and the display portion 222 is provided so as to be rotatable about the hinge portion 223 as a rotational axis in a rotational direction shown in FIG. 8. That is, the body 221 supports the display portion 222 so as to be rotatable about the hinge portion 223 as the rotational axis.

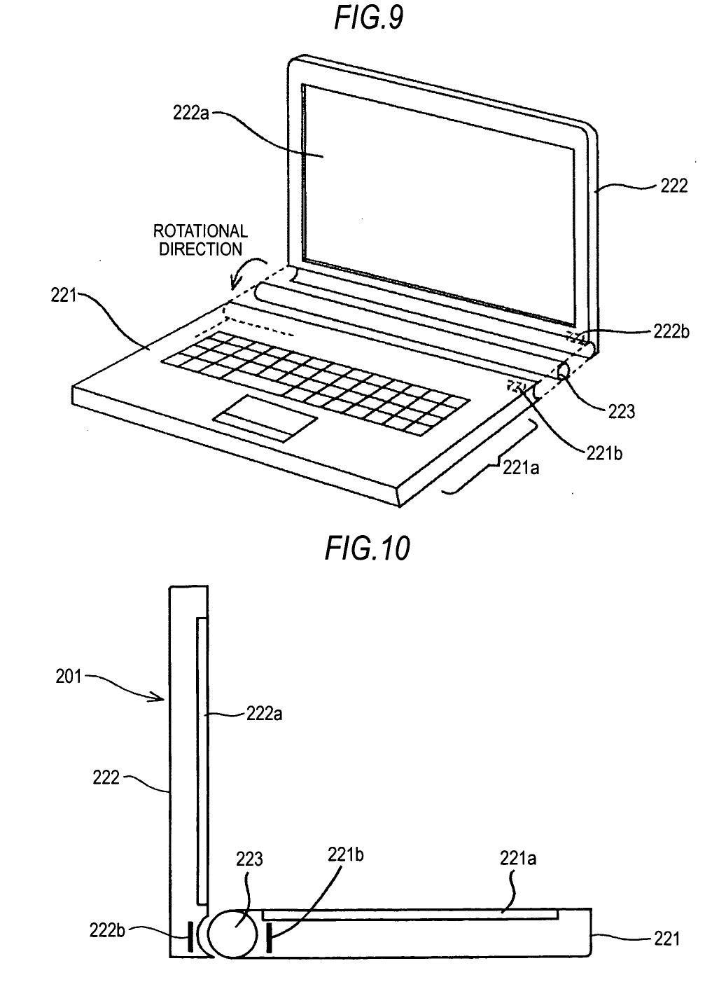

Next, FIG. 9 shows the body 221 to the hinge portion 223 obtained by disassembling the notebook PC 201.

The coupler 221b of the body 221 and the coupler 222b of the display portion 222 are formed so that the positional relation between the coupler 221b and coupler 222b does not change in the rotational axis direction of the hinge portion 223 even when the display portion 222 is rotated about the hinge portion 223 as the rotational axis in the rotational direction.

Therefore, the positional relation between the coupler 221b and the coupler 222b is constantly the same positional relation in the rotational axis direction.

Accordingly, in the following explanation in the sixth embodiment, only positional relations of the horizontal direction and the vertical direction in FIG. 8 and FIG. 10 are considered without considering the positional relation in the normal line direction (rotational axis direction of the hinge portion 223 in FIG. 9) with respect to the drawings of FIG. 8 and FIG. 10.

When the display portion 222 is in the closed state as shown in FIG. 8, transmitting/receiving surfaces of the coupler 221b and the coupler 222b are arranged in a state in which they are orthogonal to each other, that is, they are not arranged face to face to each other.

Since the coupler 221b and the coupler 222b are not arranged so as to face each other, it is difficult to perform the close-range high speed wireless communication, and the close-range high speed wireless communication using the coupler 221b and the coupler 222b is not started between the body 221 and the display portion 222.

Next, FIG. 10 shows an appearance example of the notebook PC 201 seen from a side surface in a state in which the display portion 222 is opened (a state in which the body 221 is not in contact with the display portion 222).

When the display portion 222 is in the opened state as shown in FIG. 10, the transmitting/receiving surfaces of the coupler 221b and the coupler 222b are arranged at close range so as to face each other.

In this case, the close-range high speed wireless communication using the coupler 221b and the coupler 222b is started between the body 221 and the display 222 in response to the arrangement of the transmitting/receiving surfaces facing each other.

In the sixth embodiment, the coupler 221b and the coupler 222b are provided so that the transmitting/receiving surface of the coupler 221b of the body 221 and the transmitting/receiving surface of the coupler 222b of the display portion 222 are arranged so as to be orthogonal to each other when the display portion 222 is in the closed state (the state shown in FIG. 8), as well as so that the transmitting/receiving surface of the coupler 221b of the body 221 and the transmitting/receiving surface of the coupler 222b of the display portion 222 are arranged so as to face each other when the display portion 222 is in the opened state (for example, the state shown in FIG. 10).

Accordingly, the notebook PC 201 performs the close-range high speed wireless communication when the display portion 222 is in the opened state to thereby allow the display portion 222 to display a display screen as well as does not perform the close-range high speed wireless communication when the display portion 222 is in the closed state to thereby allow the display portion 222 to display the display screen, therefore, power to be supplied to the display portion 222 can be saved as compared with the case in which the display screen is constantly displayed by the display portion 222.

Since data is exchanged by the close-range high speed wireless communication by radio in the sixth embodiment, it is not necessary to connect the body 221 to the display portion 222 by wire.

### Seventh Embodiment

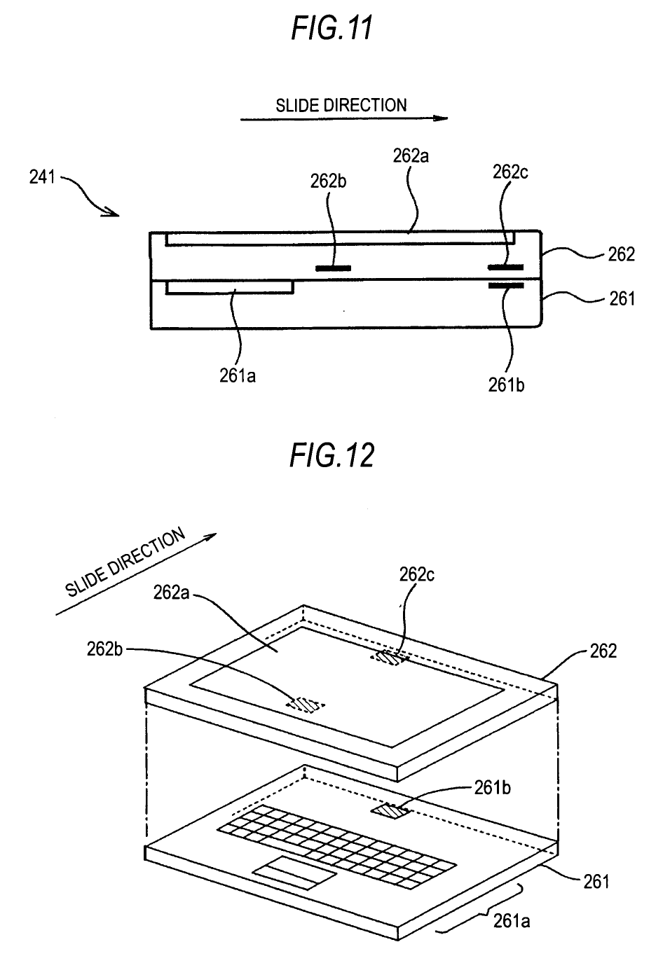

Next, a cellular phone device 241 according to a seventh embodiment will be explained with reference to FIG. 11 to FIG. 13.

FIG. 11 shows an appearance example of the cellular phone device 241 seen from a side surface.

The cellular phone device 241 includes a body 261 and a display portion 262 which can slide in the right direction (slide direction) in the drawing with respect to the body 261. In FIG. 11, the cellular phone device 241 is in the state in which the display portion 262 is closed (the body 261 is in absolute contact with the display portion 262).

The body 261 includes, in addition to an operation portion 261a such as a keyboard, a coupler 261b formed in the same manner as the coupler 21d of FIG. 1. The body 261 supports the display portion 262 so as to slide.

The display portion 262 includes, in addition to an LCD 262a, couplers 262b, 262c formed in the same manner as the coupler 22d of FIG. 1.

Next, FIG. 12 shows an appearance example of the body 261 and the display portion 262 obtained by disassembling the cellular phone device 241.

As shown in FIG. 12, the coupler 261b of the body 261 and the couplers 262b, 262c of the display portion 262 are formed so that the positional relation between the coupler 261b and the couplers 262b, 262c does not change in the direction vertical to the slide direction even when the display portion 262 is slid in the slide direction.

Therefore, the positional relation between the coupler 261b and the coupler 262b is constantly in the same positional relation in the direction vertical to the slide direction.

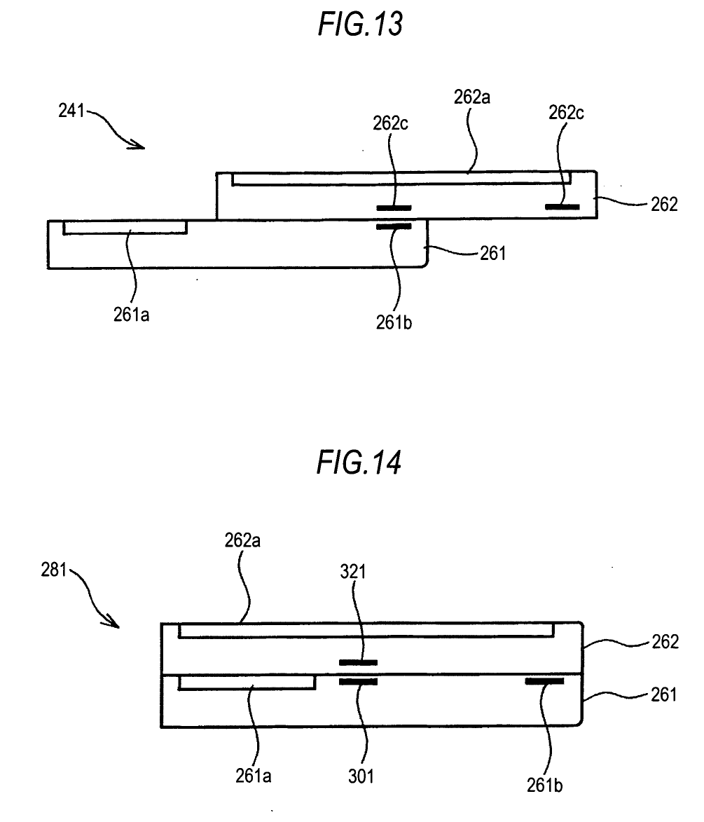

Accordingly, in the following explanation in the seventh embodiment, only positional relations of the horizontal direction and the vertical direction in FIG. 11 and FIG. 13 are considered without considering the positional relation in the normal line direction (direction vertical to the slide direction in FIG. 12) with respect to the drawings of FIG. 11 and FIG. 13.

When the display portion 262 is in the closed state as shown in FIG. 11, the transmitting/receiving surface of the coupler 261b of the body 261 and the transmitting/receiving surface of the coupler 262c of the display portion 262 are arranged so as to face each other at close range.

In this case, the close-range high speed wireless communication using the coupler 261b and the coupler 262c is started between the body 261 and the display portion 262 in response to the arrangement of the respective transmitting/receiving surfaces facing each other.

Next, FIG. 13 shows an appearance example of the cellular phone device 241 seen from a side surface in a state in which the display portion 262 is in the opened state by allowing the display portion 262 of the cellular phone device 241 of FIG. 11 to slide in the slide direction (a state in which the body 261 is in contact with the display portion 262 only at a part).

When the display portion 262 is in the opened state as shown in FIG. 13, the transmitting/receiving surface of the coupler 261b of the body 261 and the transmitting/receiving surface of the coupler 262b of the display portion 262 are arranged so as to face each other at close range.

In this case, the close-range high speed wireless communication using the coupler 261b and the coupler 262b is started between the body 261 and the display portion 262 in response to the arrangement of the respective transmitting/receiving surfaces facing each other.

In the seventh embodiment, when the display portion 262 is in the closed state (the state shown in FIG. 11), the transmitting/receiving surface of the coupler 261b of the body 261 and the coupler 262c of the display portion 262 are arranged face to face, and when the display portion 262 is in the opened state (the state shown in FIG. 13), the transmitting/receiving surface of the coupler 261b of the body 261 and the coupler 262b of the display portion 262 are arranged face to face.

When the respective transmitting/receiving surfaces of couplers are arranged so as to face each other, the close-range high speed wireless communication by radio is performed.

Therefore, it is not necessary to connect the body 261 and the display portion 262 by wire.

Incidentally, one coupler 261b is provided at the body 261 and two couplers 262b, 262c are provided at the display portion 262 in the seventh embodiment, however, it is also preferable that two couplers are provided at the body 261 and one coupler is provided at the display portion 262.

Next, a cellular phone device 281 in which two couplers are provided in the body 261 and one coupler is provided in the display portion 262 will be explained with reference to FIG. 14.

### Eighth Embodiment

FIG. 14 shows an appearance example of the cellular phone device 281 seen from a side surface according to an eighth embodiment.

In the cellular phone device 281, the same signs are given to components formed in the same manner as the cellular phone device 241 according to the seventh embodiment, therefore, explanation thereof will be omitted below.

That is, the cellular phone device 281 is formed in the same manner as the cellular phone device 241 except that a coupler 301 is newly provided at the body 261 as well as a coupler 321 is provided instead of the couplers 262b, 262c at the display portion 262.

When the display portion 262 is in the closed state in the cellular phone device 281, the coupler 301 of the body 261 is arranged face to face with the coupler 321 of the display portion 262, so that the close-range high speed wireless communication can be performed.

On the other hand, when the display portion 262 is in the opened state in the cellular phone device 281, the coupler 261b of the body 261 and the coupler 321 of the display portion 262 are arranged face to face, so that the close-range high speed wireless communication can be performed.

### 9. Modification Example

In the second and third embodiments, the couplers 61c, 61d are provided at edge portions of the body 61 and the couplers 62d, 62e or the coupler 101 are provided at a corner portion of the display portion 62, however, it is not limited to this.

For example, it is preferable that one coupler is provided at the center of the convex portion 61b instead of the couplers 61c, 61d in the body 61, and couplers are provided inside the concave portions 62b, 62c respectively, instead of the couplers 62d, 62e or the coupler 101 in the display portion 62.

In the above case, two couplers in the body 61 can be reduced to one.

In the first, second embodiments as well as the fourth to eighth embodiments, the close-range high speed wireless communication is performed when the respective transmitting/receiving surfaces of the couplers are arranged face to face (the angle formed by the respective transmitting/receiving surfaces is 0 degree), and in the third embodiment, the close-range high speed wireless communication is performed when the angle formed by the respective transmitting/receiving surfaces of the couplers is 45 degrees, however, it is not limited to these.

That is, it is possible to perform the close-range high speed wireless communication when the respective transmitting/receiving surfaces of the couplers are arranged in a position in which the close-range high speed wireless communication can be performed (for example, a position in which the angle formed by the respective transmitting/receiving surfaces of the couplers is 0 or more and less than 90 degrees).

In the first to eighth embodiments, cases in which the invention is applied to a personal computer and a cellular phone have been explained, however, the invention can be applied to any information processing device as long as the device includes a display integrally.

Embodiments are not limited to the above first to eighth embodiments, and can be variously changed within a scope not departing from the gist of the invention.

It should be understood by those skilled in the art that various modifications, combinations, sub-combinations and alterations may occur depending on design requirements and other factors insofar as they are within the scope of the appended claims or the equivalents thereof.

What is claimed is:

1. An information processing device, comprising: a display means including a receiving surface for receiving data transmitted by wireless communication; and
a supporting means including a transmitting surface for transmitting the data by the wireless communication and supporting the display means,
wherein the supporting means supports the display means in a position in which the wireless communication can be performed.

2. The information processing device according to claim 1,
wherein the supporting means supports the display means in a position in which the data transmitted from the transmitting surface can be received only by the receiving surface.

3. The information processing device according to claim 2,
wherein the supporting means supports the display means so as to be detachable.

4. The information processing device according to claim 3,
wherein the display means has a rectangular parallelepiped shape, and
the supporting means supports the display means in landscape orientation or in portrait orientation.

5. The information processing device according to claim 4,
wherein the display means includes
a first receiving surface receiving the data transmitted from the transmitting surface by the wireless communication when the display means is supported in landscape orientation, and
a second receiving surface receiving the data transmitted from the transmitting surface by the wireless communication when the display means is supported in portrait orientation.

6. The information processing device according to claim 5,
wherein the first receiving surface and the second receiving surface are the same receiving surface.

7. The information processing device according to claim 3,
wherein the supporting means supports the display means so as to be rotatable about the supporting means as a rotational axis.

8. The information processing device according to claim 7,
wherein the supporting means supports the display means in a position in which the wireless communication is not capable of being performed when the wireless communication is not performed.

9. The information processing device according to claim 2,
wherein the supporting means supports the display means so as to slide in a given direction.

10. The information processing device according to claim 9,
wherein the display means includes
a first receiving surface receiving the data transmitted from the transmitting surface by the wireless communication when the display means is supported in the state of being slid in the given direction, and
a second receiving surface different from the first receiving surface, receiving the data transmitted from the transmitting surface by the wireless communication when the display device is supported in the state of not being slid in the given direction.

11. The information processing device according to claim 9,
wherein the supporting means includes
a first transmitting surface transmitting the data by the wireless communication when the display means is supported in the state of being slid in the given direction, and
a second transmitting surface different from the first transmitting surface, transmitting the data by the wireless communication when the display device is supported in the state of not being slid in the given direction.

12. The information processing device according to claim 3,
wherein the supporting means supports the display means so that a display screen of the display means is directed to a given direction or a direction opposite to the given direction.

13. The information processing device according to claim 2,
wherein the display means displays an image corresponding to the data received by the receiving surface, and
the transmitting surface included in the supporting means transmits the data at a transfer speed corresponding to a display speed of the image displayed by the display means.

14. The information processing device according to claim 1,
wherein the supporting means supports the display means in a position in which the transmitting surface faces the receiving surface.

15. The information processing device according to claim 1,
wherein the transmitting surface included in the supporting means and the receiving surface included in the display means perform the wireless communication by TransferJet (Registered Trademark of Sony Corporation).
